(19) United States
(12) Patent Application Publication
(10) Pub. No.: US 2018/0261515 A1
(43) Pub. Date: Sep. 13, 2018

(54) SEMICONDUCTOR STRUCTURES AND FABRICATION METHODS THEREOF

(71) Applicants: Semiconductor Manufacturing International (Shanghai) Corporation, Shanghai (CN); Semiconductor Manufacturing International (Beijing) Corporation, Beijing (CN)

(72) Inventors: Yan WANG, Shanghai (CN); Shi Liang JI, Shanghai (CN); Hai Yang ZHANG, Shanghai (CN)

(21) Appl. No.: 15/914,146

(22) Filed: Mar. 7, 2018

(30) Foreign Application Priority Data
Mar. 7, 2017 (CN) 201710131086.5

(51) Int. Cl. H01L 21/8238; H01L 27/092; H01L 29/49; H01L 29/51; H01L 21/28; H01L 21/3215; H01L 21/225; H01L 21/324; H01L 29/06

(52) U.S. Cl. CPC H01L 21/823857; H01L 27/092; H01L 29/4966; H01L 29/517; H01L 29/518; H01L 29/0649; H01L 21/28088; H01L 21/28176; H01L 21/3215; H01L 21/225; H01L 21/324; H01L 21/823842

(57) ABSTRACT

A method for fabricating a semiconductor structure includes providing a substrate including a first region and a second region, forming a dielectric layer with a first opening in the first region and a second opening in the second region, forming a functional layer, forming a first doped layer containing first work function adjusting ions in the first opening, forming a second doped layer containing second work function adjusting ions in the second opening, performing an annealing process to diffuse the first work function adjusting ions into the functional layer in the first opening and the second work function adjusting ions into the functional layer in the second opening, removing the first doped layer and the second doped layer, forming a work function layer in both the first opening and the second opening, and forming a gate electrode layer in each of the first opening and the second opening.

### CROSS-REFERENCES TO RELATED APPLICATIONS

This application claims the priority of Chinese Patent Application No. CN201710131086.5, filed on Mar. 7, 2017, the entire content of which is incorporated herein by reference.

### FIELD OF THE DISCLOSURE

The present disclosure generally relates to the field of semiconductor fabrication technology and, more particularly, relates to semiconductor structures and fabrication methods thereof.

### BACKGROUND

With continuous development of semiconductor technology, the degree of integration of semiconductor devices is continually increased. More transistors are required to be formed on a chip.

The threshold voltage, as an important parameter of a transistor, has significant impacts on the performance of the transistor. Transistors with different functions often have different requirements on their threshold voltages. Therefore, during the process to form the transistors, the threshold voltages of different transistors may need to be adjusted. In order to adjust the threshold voltage for each transistor, a work function layer is often formed on the gate dielectric layer of the transistor. By varying the thickness and/or the material of the work function layer for different transistors, the transistors may then have different threshold voltages.

However, the performance of semiconductor structures formed by existing methods may still need to be improved. The disclosed semiconductor structures and fabrication methods thereof are directed to solve one or more problems set forth above and other problems in the art.

### BRIEF SUMMARY OF THE DISCLOSURE

One aspect of the present disclosure includes a method for fabricating a semiconductor structure. The method for fabricating the semiconductor structure includes providing a substrate including a first region and a second region, and forming a dielectric layer on the first region and the second region of the substrate. The dielectric layer has a first opening in the first region and a second opening in the second region. The method also includes forming a functional layer on bottom and sidewall surfaces of each of the first opening and the second opening, forming a first doped layer containing first work function adjusting ions on a first portion of the functional layer formed on the bottom and the sidewall surfaces of the first opening, forming a second doped layer containing second work function adjusting ions on a second portion of the functional layer formed on the bottom and the sidewall surfaces of the second opening, performing an annealing process to diffuse the first work function adjusting ions into the first portion of the functional layer formed in the first opening and to diffuse the second work function adjusting ions into the second portion of the functional layer formed in the second opening, removing the first doped layer and the second doped layer, forming a work function layer on the functional layer in both the first opening and the second opening, and forming a gate electrode layer in each of the first opening and the second opening on the work function layer.

Another aspect of the present disclosure provides a semiconductor structure. The semiconductor structure includes a substrate including a first region and a second region, and a dielectric layer formed on the first region and the second region of the substrate. The dielectric layer has a first opening in the first region and a second opening in the second region. The semiconductor structure also includes a functional layer covering bottom and sidewall surfaces of the first opening and the second opening. A first portion of the functional layer formed on the bottom and the sidewall surfaces of the first opening contains first work function adjusting ions, and a second portion of the functional layer formed on the bottom and the sidewall surfaces of the second opening contains second work function adjusting ions. The semiconductor structure further includes a work function layer formed on the functional layer in the first opening and the second opening, and a gate electrode layer formed on the work function layer in each of the first opening and the second opening.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-3 illustrate schematic cross-section views of semiconductor structures at certain stages of a fabrication process; and

FIGS. 4-12 illustrate schematic cross-section views of semiconductor structures at certain stages of an exemplary fabrication process consistent with various disclosed embodiments in the present disclosure; and

FIG. 13 illustrates a flowchart of an exemplary method for fabricating a semiconductor structure consistent with various disclosed embodiments in the present disclosure.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

As described above, the performance of semiconductor structures formed by existing methods may still need to be improved. In the following, a method for fabricating a semiconductor structure is provided to illustrate the reasons that may cause undesired performance for the formed semiconductor structure.

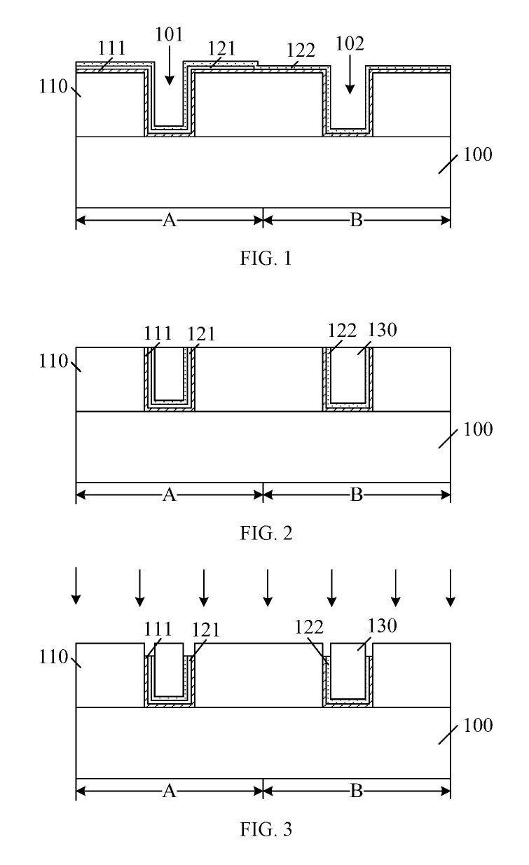

FIGS. 1-3 illustrate schematic cross-section views of semiconductor structures at certain stages of a fabrication method.

Referring to FIG. 1, a substrate 100 is provided. The substrate 100 includes a first region A and a second region B. A dielectric layer 110 is formed on the substrate 100 in both the first region A and the second region B. Moreover, a first opening 101 is formed in the dielectric layer 110 of the first region A, and a second opening 102 is formed in the dielectric layer 110 of the second region B.

Further, a gate dielectric layer 111 is formed on the bottom and the sidewall surfaces of both the first opening 101 and the second opening 102. A first work function layer 121 is then formed on the portion of the gate dielectric layer 111 in the first opening 101. Further, a second work function layer 122 is formed on the first work function layer 121 in the first opening 101 and also on the gate dielectric layer 111 in the second opening 102.

Referring to FIG. 2, after forming the second work function layer 122, a gate electrode layer 130 is formed in each of the first opening 101 and the second opening 102.

Referring to FIG. 3, an etching process is performed on the gate dielectric layer 111, the first work function layer 121, and the second work function layer 122. As such, a portion of the sidewall surfaces of the gate electrode layer 130 formed in the first opening 101 (referring to FIG. 1) is exposed by removing a portion of the gate dielectric layer 111, the first work function layer 121, and the second work function layer 122 in the first opening 101, and a portion of the sidewall surfaces of the gate electrode layer 130 formed in the second opening 102 (referring to FIG. 1) is exposed by removing a portion of the gate dielectric layer 111 and the second work function layer 122 in the second opening 102. Further, during the etching process to partially remove the gate dielectric layer 111, the first work function layer 121, and the second work function layer 122, a top portion of each gate electrode layer 130 is also removed. Moreover, the etching rate on the gate electrode layer 130 is smaller than the etching rate on the gate dielectric layer 111, the first work function layer 121, and the second work function layer 122 such that a portion of the sidewall surfaces of the gate electrode layer 130 can be exposed after the etching process.

In a subsequent process, a contact plug is formed on each gate electrode layer 130 to electrically connect with the gate electrode layer 130.

According to the fabrication method and the semiconductor structure described above, a portion of the gate dielectric layer 111, the first work function layer 121, and the second work function layer 122, as well as a gate dielectric layer 130 are formed in the first opening 101 of the semiconductor structure; a portion of the gate dielectric layer 111 and the second work function layer 122, as well as a gate dielectric layer 130 are formed in the second opening 102 of the semiconductor structure. Moreover, because the dimension of the first opening 101 and the dimension of the second opening 102 are identical, the dimension of the gate electrode layer 130 formed in the first opening 101 along a direction perpendicular to the extending direction of the gate electrode layer 130 is different from the dimension of the gate electrode layer 130 formed in the second opening 102 along a direction perpendicular to the extending direction of the gate electrode layer 130.

Specifically, along the direction perpendicular to the extending direction of the gate electrode layer 130 and parallel to the surface of the substrate 101, the dimension of the gate electrode layer 130 formed in the first opening 101 is smaller than the dimension of the gate electrode layer 130 formed in the second opening 102. Accordingly, during the etching process to partially remove the gate dielectric layer 111, the first work function layer 121, and the second work function layer 122, the etching depth for the gate electrode layer 130 in the first opening 101 along the direction perpendicular to the surface of the substrate 100 is relatively large, and thus the top portion of the sidewall surfaces of the gate electrode layer 130 in the first opening 101 cannot be easily exposed after partially removing the dielectric layer 111, the first work function layer 121, and the second work function layer 122 in the first opening 101; however, the etching depth for the gate electrode layer 130 in the second opening 102 along the direction perpendicular to the surface of the substrate 100 is relatively small, and thus the top portion of the sidewall surfaces of the gate electrode layer 130 in the second opening 102 can be easily exposed after partially removing the dielectric layer 111 and the second work function layer 122 in the second opening 102.

Therefore, when the amount of the gate dielectric layer 111, the first work function layer 121, and the second work function layer 122 removed by etching is relatively small, the gate electrode layer 130 in the first opening 101 may be difficult to be exposed, which is detrimental to increasing the contact area between the gate electrode layer 130 and the corresponding contact plug, and thus detrimental to decreasing the contact resistance. When the amount of the gate dielectric layer 111, the first work function layer 121, and the second work function layer 122 removed by etching is relatively large, the gate electrode layer 130 in the second opening 102 may be overly etched such that the defect level in the gate electrode layer 130 formed in the second opening 102 may be increased, degrading the performance of the formed semiconductor structure.

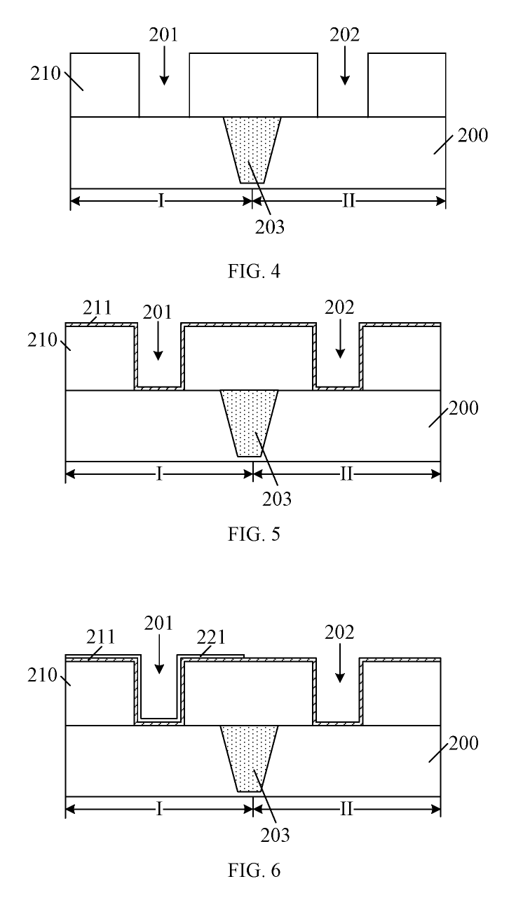

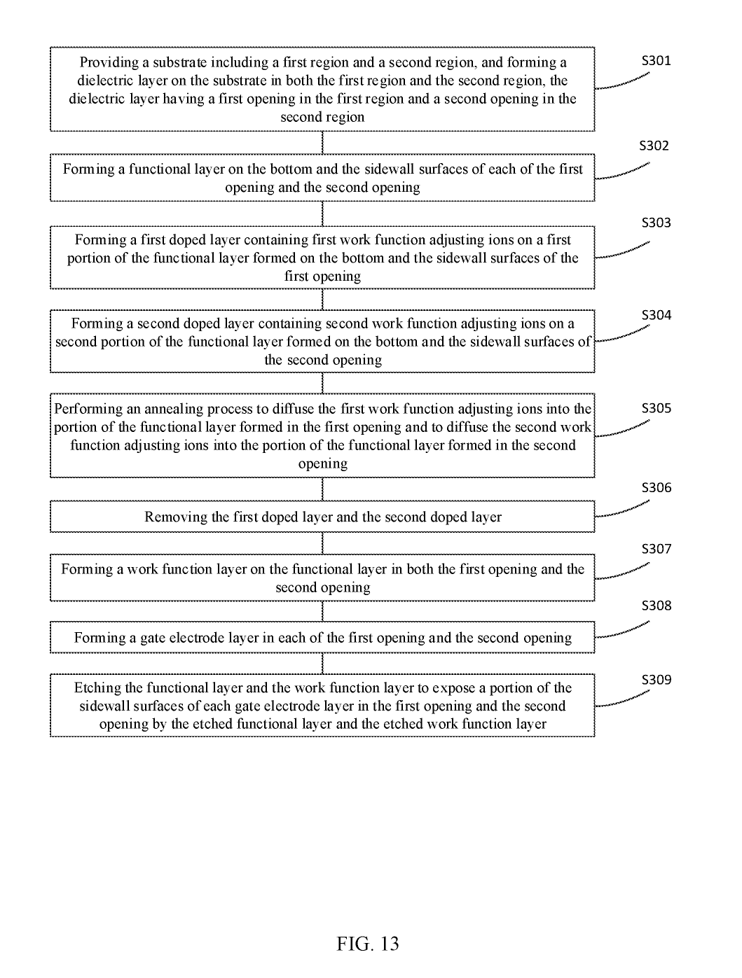

In view of the problems described above, the present disclosure provides a method for fabricating a semiconductor structure. FIG. 13 illustrates a flowchart of an exemplary method for fabricating a semiconductor structure consistent with various disclosed embodiments in the present disclosure. FIGS. 4-12 illustrate schematic cross-section views of semiconductor structures at certain stages of the fabrication process.

Referring to FIG. 13, at the beginning of the fabrication process, a substrate including a first region and a second region may be provided, and a dielectric layer may be formed on the substrate in both the first region and the second region, and the dielectric layer may have a first opening in the first region and a second opening in the second region (S301). FIG. 4 illustrates a schematic cross-section view of a corresponding semiconductor structure.

Referring to FIG. 4, a substrate 200 is provided. The substrate 200 may include a first region I and a second region II. A dielectric layer 210 may be formed on the substrate 200 in both the first region I and the second region II. A first opening 201 may be formed in the dielectric layer 210 in the first region I, and a second opening 202 may be formed in the dielectric layer in the second region II.

The first region I may be used to form N-type metal-oxide-semiconductor (NMOS) transistors, and the second region II may be used to form P-type metal-oxide-semiconductor (PMOS) transistors. In other embodiment, the first region may be used to form PMOS transistors, and the second region may be used to form NMOS transistors.

In one embodiment, the number of the NMOS transistors to be formed in the first region I may be one or more than one and the number of the PMOS transistors to be formed in the second region II may also be one or more than one. For illustration purpose, the semiconductor structure shown in FIG. 4 is described to have only one NMOS transistor to be formed in the first region I and also only one PMOS transistor to be formed in the second region II.

The dielectric layer 210 may be used to electrically isolate the subsequently-formed gate electrode layers. The first opening 201 and the second opening 202 may be used to provide spaces for subsequently-formed gate electrode layers.

The substrate 200 may be made of silicon, germanium, SiGe, silicon on insulator (SOI), germanium on insulator (GOI), SiGe on insulator, or any other appropriate semiconductor materials. In one embodiment, the substrate 200 is made of silicon.

In one embodiment, the dielectric layer 210, the first opening 201, and the second opening 202 may be formed by a process including the following steps. First, a first dummy gate structure may be formed on the substrate 200 in the first region I. A second dummy gate structure may be formed on the substrate 200 in the second region II. The dielectric layer 210 may then be formed on the substrate 200. The dielectric layer 210 may cover the sidewall surfaces of the first dummy gate structure and the sidewall surfaces of the second dummy gate structure. Further, the first dummy gate structure may be removed to form a first opening 201 in the dielectric layer 210 of the first region I. The second dummy gate structure may be removed to form a second opening 202 in the dielectric layer 210 of the second region II. The first dummy gate structure and the second dummy gate structure may or may not be formed simultaneously, and also, the first dummy gate structure and the second dummy gate structure may or may not be removed simultaneously.

In one embodiment, the dielectric layer 210 is made of SiOx. In other embodiment, the dielectric layer 210 may also be made of any other dielectric material.

Moreover, in one embodiment, an isolation structure 203 may be formed on the substrate 200. The isolation structure 203 may be used to electrically isolate the first region I and the second region II. The isolation structure 203 may be made of SiOx.

Further, returning to FIG. 13, a functional layer may be formed on the bottom and the sidewall surfaces of each of the first opening and the second opening (S302). FIG. 5 illustrates a schematic cross-section view of a corresponding semiconductor structure.

Referring to FIG. 5, a functional layer 211 may be formed on the bottom and the sidewall surfaces of the first opening 201 and the second opening 202. The functional layer 211 may be used to contain first work function adjusting ions and/or second work function adjusting ions in a subsequent process such that the threshold voltages of the transistors to be formed may be adjusted.

For example, in a subsequent process, ions may be doped into the functional layer 211 to adjust the threshold voltages for the NMOS transistor and the PMOS transistor to be formed. Specifically, in one embodiment, by introducing doping ions into the functional layer 211, the threshold voltages of the NMOS transistor and the PMOS transistor may be adjusted. In other embodiment, introducing doping ions into the functional layer may increase the threshold voltages for the NMOS transistor and the PMOS transistor.

In one embodiment, the functional layer 211 may be the gate dielectric layer of the transistor to be formed. The functional layer 211 serving as the gate dielectric layer for the formed transistor may simplify the process flow. In other embodiment, the functional layer may include the gate dielectric layer formed on the bottoms of the first opening and the second opening and a covering layer formed on the gate dielectric layer. The covering layer may be made of TiN or TaN. Alternatively, the functional layer may only include the covering layer.

In one embodiment, the functional layer 211 may be made of a high-k dielectric material (k greater than 3.9), such as HfO₂, La₂O₃, HfSiON, HfAlO₂, ZrO₂, Al₂O₃, HfSiO₄, etc. The functional layer 211 may be formed by a process including chemical vapor deposition (CVD). The thickness of the functional layer 211 may be in a range of approximately 18 Å to 22 Å.

Further, returning to FIG. 13, a first doped layer containing first work function adjusting ions may be formed on the surface of a first portion of the functional layer formed on the bottom and the sidewall surfaces of the first opening (S303). FIG. 6 illustrates a schematic cross-section view of a corresponding semiconductor structure.

Referring to FIG. 6, a first doped layer 221 may be formed on a first portion of the functional layer 211 on the bottom and the sidewall surfaces of the first opening 201. The first doped layer 221 may contain first work function adjusting ions.

In a subsequent process, the first doped layer 221 may be used to dope the first portion of the functional layer 211 formed on the bottom and the sidewall surfaces of the first opening 201. By doping the first work function adjusting ions into the first portion of the functional layer 211 under the first doped layer 221, the work function of the functional layer 211 in the first region I may be adjusted, and thus, the threshold voltage of the NMOS transistor to be formed may also be adjusted.

In one embodiment, the first doped layer 221 may be formed by a process including forming a first initially-doped layer on the functional layer 211 in both the first region I and the second region II, and then forming a first doped layer 221 by removing the portion of the first initially-doped layer formed in the second region II.

In one embodiment, the first doped layer 221 is made of TiN or TaN.

In one embodiment, the first work function adjusting ions may be Mg ions. In a subsequent process, doping Mg ions into the functional layer 211 may increase the work function of the functional layer 211, and thus reduce the difference in the Fermi energy level between the gate electrode layer and the gate dielectric layer in the formed NMOS transistor. Therefore, the threshold voltage in the formed NMOS transistor may be reduced.

When the concentration of the first work function adjusting ions in the first doped layer 221 is too large, during a subsequently-performed annealing process, the concentration of the first work function adjusting ions in the functional layer 211 of the first region I may become overly large, such that the work function of the functional layer 211 in the first region I may also become too large, which is detrimental to reducing the difference between the Fermi energy level of the functional layer 211 in the first region I and the Fermi energy level of the subsequently-formed gate electrode layer in the first opening 201, and thus detrimental to reducing the threshold voltage of the formed NMOS transistor.

When the concentration of the first work function adjusting ions in the first doped layer 221 is too small, during a subsequently-performed annealing process, the concentration of the first work function adjusting ions in the functional layer 211 of the first region I may also become too small, which is detrimental to increasing the work function of the functional layer 211 in the first region I, and also detrimental to decreasing the difference between the Fermi energy level of the functional layer 211 in the first region I and the Fermi energy level of the subsequently-formed gate electrode layer in the first opening 201.

In one embodiment, the concentration of the first work function adjusting ions in the first doped layer 221 may be in a range of approximately 4E14 atom/cm² to 6E14 atom/cm².

Moreover, when the thickness of the first doped layer 221 is too large, the process to remove the first doped layer 221 in a subsequent process may be difficult. When the thickness of the first doped layer 221 is too small, the total number of first work function adjusting ions contained in the first doped layer 221 may easily become too small. As such, during the subsequently-performed annealing process, the functional layer 211 may not be easily doped with the first work function adjusting ions. That is, the concentration of the first work function adjusting ions in the first portion of the functional layer 211 after the annealing process may be small. In one embodiment, the thickness of the first doped layer 221 is in a range of approximately 8 Å to 10 Å.

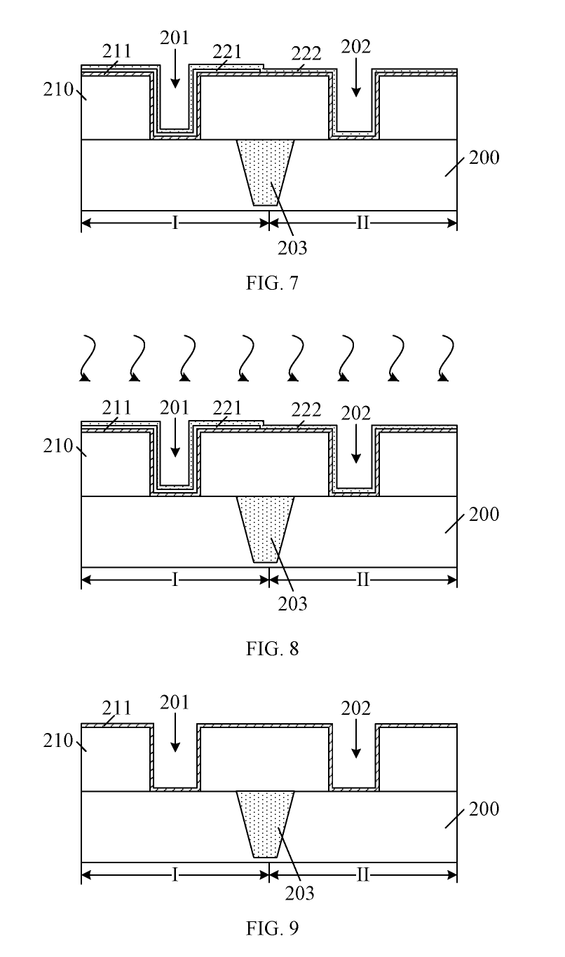

Further, returning to FIG. 13, a second doped layer containing second work function adjusting ions may be formed on a second portion of the functional layer formed on the bottom and the sidewall surfaces of the second opening (S304). FIG. 7 illustrates a schematic cross-section view of a corresponding semiconductor structure.

Referring to FIG. 7, a second doped layer 222 may be formed on a second portion of the functional layer 211 on the bottom and the sidewall surfaces of the second opening 202. The second doped layer 222 may contain second work function adjusting ions.

In a subsequent process, the second doped layer 222 may be used to dope the second portion of the functional layer 211 formed on the bottom and the sidewall surfaces of the second opening 202. By doping the second work function adjusting ions into the second portion of the functional layer 211 under the second doped layer 222, the work function of the functional layer 211 in the second region II may be adjusted, and thus the difference in the Fermi energy level between the functional layer 211 and the gate electrode layer of the subsequently-formed PMOS transistor may also be reduced. As such, the threshold voltage of the PMOS transistor to be formed may be adjusted.

In one embodiment, the second doped layer 222 may also be formed on the first doped layer 221. In other embodiment, the second doped layer may only be formed in the second region.

In one embodiment, the second doped layer 222 is made of AlOₓ. In other embodiment, the second doped layer may also be made of TiN doped with Al ions or TaN doped with Al ions.

In one embodiment, the second work function adjusting ions may be Al ions. In a subsequent process, the second doped layer 222 may be used to dope Al ions into the functional layer 211 such that the work function of the second portion of the functional layer 211 covered by the second doped layer 222 may be increased. As such, the difference between the Fermi energy level of the functional layer 222 and the Fermi energy level of the subsequently-formed gate electrode layer in the second opening 202 may be reduced, and thus, the threshold voltage in the formed PMOS transistor may also be reduced.

In one embodiment, the second doped layer 222 is made of AlOₓ, which containing Al ions. Therefore, the second doped layer 222 may not require any additional doping. In other embodiment, the second doped layer may also be made of TiN or TaN, and accordingly, during the formation of the second doped layer, the second work function adjusting ions, i.e. Al ions, may need to be doped into the second doped layer.

When the thickness of the second doped layer 222 is too large, the process to remove the second doped layer 222 in a subsequent process may be difficult. When the thickness of the second doped layer 222 is too small, the total number of second work function adjusting ions contained in the second doped layer 222 may easily become too small. As such, during the subsequently-performed annealing process, the functional layer 211 may not be easily doped with the second work function adjusting ions. That is, the concentration of the second work function adjusting ions in the second portion of the functional layer 211 after the annealing process may be small. In one embodiment, the thickness of the first doped layer 221 is in a range of approximately 8 Å to 10 Å.

Further, returning to FIG. 13, after forming the first doped layer and the second doped layer, an annealing process may be performed to diffuse the first work function adjusting ions into the first portion of the functional layer formed in the first opening and to diffuse the second work function adjusting ions into the second portion of the functional layer formed in the second opening (S305). FIG. 8 illustrates a schematic diagram of performing an annealing process.

Referring to FIG. 8, after forming the first doped layer 221 and the second doped layer 222, an annealing process may be performed such that the first work function adjusting ions may diffuse into the first portion of the functional layer 211 formed in the first opening 201 and the second work function adjusting ions may diffuse into the second portion of the functional layer 211 formed in the second opening 202. Therefore, the annealing process may be used to diffuse the first work function adjusting ions and the second work function adjusting ions into the functional layer 211.

During the annealing process, the first work function adjusting ions in the first doped layer 221 may diffuse into the first portion of the functional layer 211 formed on the bottom and the sidewall surfaces of the first opening 201 to adjust the work function of the first portion of the functional layer 211 in the first opening 201, and thus, the threshold voltage of the NMOS transistor formed in the first region I may be further adjusted. Moreover, the second work function adjusting ions in the second doped layer 222 may diffuse into the second portion of the functional layer 211 formed on the bottom and the sidewall surfaces of the second opening 202 to adjust the work function of the second portion of the functional layer 211 in the second opening 202, and thus, the threshold voltage of the PMOS transistor formed in the second region II may be further adjusted. As such, the threshold voltages of the transistors formed in the first region I and the second region II may meet different design requirements.

In one embodiment, the second doped layer 222 may also be formed on the first doped layer 221 which is formed on the bottom and the sidewall surfaces of the first opening 201. Therefore, during the annealing process, the second work function adjusting ions in the second doped layer 222 may also diffuse into the first portion of the functional layer 211 formed on the bottom and the sidewall surfaces of the first opening 201, and thus also adjust the threshold voltage of the formed NMOS transistor.

When the annealing temperature is too low and/or the annealing time is too short, the annealing process may not be conducive to the diffusion of the first work function adjusting ions and the second work function adjusting ions. Therefore, the concentration of the first work function adjusting ions and the concentration of the second work function adjusting ions may be too low to be conducive to increasing the work function value of the functional layer 211 in the first opening 201 and the second opening 202. When the annealing temperature is too high and/or the annealing time is too long, the concentration of the first work function adjusting ions and the concentration of the second work function adjusting ions may be too large. Accordingly, the work function value of the functional layer 211 may also be too large, and thus, the difference between the Fermi energy level of the functional layer 211 and the Fermi level of a subsequently-formed gate electrode layer may be increased. In one embodiment, during the annealing process, the annealing temperature may be in a range of approximately 750° C. to 900° C. and the annealing time may be in a range of approximately 10 minutes to 30 minutes.

Further, returning to FIG. 13, after performing the annealing process, the first doped layer and the second doped layer may be removed (S306). FIG. 9 illustrates a schematic cross-section view of a corresponding semiconductor structure.

Referring to FIG. 9, after performing the annealing process, the first doped layer 221 (referring to FIG. 8) and the second doped layer 222 (referring to FIG. 8) may be removed. In one embodiment, the first doped layer 221 and the second doped layer 222 may be removed by an etching process including dry etching or wet etching.

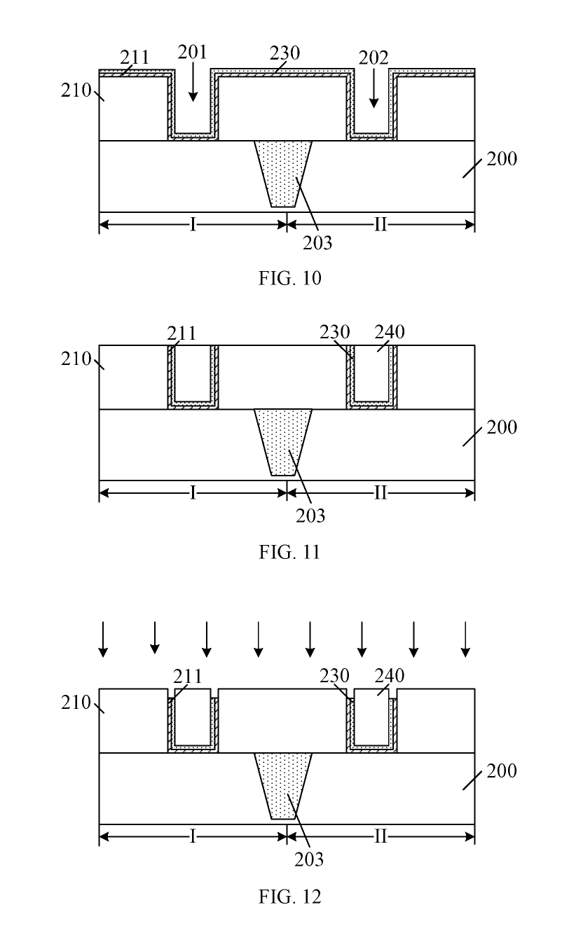

Further, returning to FIG. 13, after removing the first doped layer and the second doped layer, a work function layer may be formed on the functional layer in both the first opening and the second opening (S307). FIG. 10 illustrates a schematic cross-section view of a corresponding semiconductor structure.

Referring to FIG. 10, after removing the first doped layer 221 (referring to FIG. 8) and the second doped layer 222 (referring to FIG. 8), a work function layer 230 may be formed on the functional layer 211 in the first opening 201 and the second opening 202. The work function layer 230 may be used to adjust the threshold voltages of the NMOS transistor and the PMOS transistor formed subsequently such that the threshold voltages of the NMOS transistor and the PMOS transistor may meet the design requirements.

In one embodiment, the work function layer 230 may include a TiN layer. In other embodiment, the work function layer may also include a TaN layer or a Ti—Al alloy layer. Alternatively, the work function layer may have a multi-layer structure formed by a TaN layer and a Ti—Al alloy layer.

In one embodiment, the work function layer 230 may be formed by a process including chemical vapor deposition (CVD). Further, the thickness of the work function layer 230 may be in a range of approximately 20 Å to 40 Å.

Returning to FIG. 13, after forming the work function layer, a gate electrode layer may be formed in each of the first opening and the second opening (S308). FIG. 11 illustrates a schematic cross-section view of a corresponding semiconductor structure.

Referring to FIG. 11, after forming the work function layer 230, a gate electrode layer 240 may be formed in each of the first opening 201 (referring to FIG. 10) and the second opening 202 (referring to FIG. 10). In one embodiment, the gate electrode layer 240 is made of a metal such as tungsten.

In one embodiment, the gate electrode layer 240 may be formed by a process including the following steps. First, a metal layer may be formed in the first opening 201 and the second opening 202 as well as on the dielectric layer 210. Further, a planarization process may be performed on the metal layer to remove the portion of the metal layer formed on the dielectric layer 210. As such, a gate electrode layer 240 may be formed in the first opening 201 and another gate electrode layer 240 may be formed in the second opening 202. In one embodiment, the metal layer may be formed by a CVD process, and the planarization process may include chemical mechanical polishing (CMP).

Moreover, in one embodiment, after removing the portion of the metal layer formed on the dielectric layer 210, the fabrication process may also include removing the portion of the functional layer 211 and the work function layer 230 formed on the dielectric layer 210.

Returning to FIG. 13, further, the functional layer and the work function layer may be etched to expose a portion of the sidewall surfaces of each gate electrode layer in the first opening and the second opening by the etched functional layer and the etched work function layer (S309). FIG. 12 illustrates a schematic cross-section view of a corresponding semiconductor structure.

Referring to FIG. 12, the portion of the functional layer 211 and the work function layer 230 formed on the sidewall surfaces of the first opening 201 (referring to FIG. 10) and the second opening 202 (referring to FIG. 10) may be etched to expose a portion of the sidewall surfaces of each gate electrode layer 240.

The portion of the sidewall surfaces of each gate electrode layer 240 exposed by the functional layer 211 and the work function layer 230 may increase the contact area between a subsequently-formed contact plug and the gate electrode layer 250, and thus reduce the contact resistance between the contact plug and the gate electrode layer 240.

In one embodiment, the etching process to etch the portion of the functional layer 211 and the work function layer 230 formed on the sidewall surfaces of the first opening 201 and the second opening 202 may include a dry etching process.

According to the disclosed methods for fabricating semiconductor structures, prior to forming the gate electrode layers, a first doped layer and a second doped layer are formed on the functional layer and an annealing process is performed. During the annealing process, the first work function adjusting ions in the first doped layer can diffuse into the first portion of the functional layer formed on the bottom and the sidewall surfaces of the first opening to adjust the work function of the first portion of the functional layer in the first opening, and thus adjust the threshold voltage of the transistor to be formed in the first region. In the meantime, the second work function adjusting ions in the second doped layer can diffuse into the second portion of the functional layer formed on the bottom and the sidewall surfaces of the second opening to adjust the work function of the second portion of the functional layer in the second opening, and thus adjust the threshold voltage of the transistor to be formed in the second region. Therefore, the threshold voltages of the transistors in the first region and the second region can meet different design requirements.

Moreover, the thickness of the functional layer is uniform in the first opening and the second opening, and prior to forming the gate electrode layers, the first doped layer and the second doped layer are removed. Therefore, along the direction parallel to the surface of the substrate and also along the direction perpendicular to the surface of the substrate, the dimensions of the gate electrode layer in the first opening are the same as the dimensions of the gate electrode layer in the second opening. As such, the properties of the transistors formed in the first region and the second region may be uniform, and the performance of the semiconductor structure may be improved.

Further, the thickness of the functional layer is uniform in the first opening and the second opening, and prior to forming the gate electrode layers, the first doped layer and the second doped layer are removed. Therefore, along the direction parallel to the surface of the substrate and also along the direction perpendicular to the surface of the substrate, the dimensions of the gate electrode layer in the first opening are the same as the dimensions of the gate electrode layer in the second opening. As such, during the etching process performed on the work function layer and the functional layer, along the direction perpendicular to the surface of the substrate, the etching depth in the first opening may be the same as the etching depth in the second opening. Thus, the performance of the transistors formed in both the first region and the second region may be the same. In addition, the etching process may also be easily controlled. Specifically, when the functional layer and the work function layer formed on the sidewalls of the first opening become lower than the top surface of the gate electrode layer in the first opening, damages to the gate electrode layer in the second opening during the etching process may not be significant. In the meantime, when the functional layer and the work function layer formed on the sidewalls of the second opening become lower than the top surface of the gate electrode layer in the second opening, damages to the gate electrode layer in the first opening during the etching process may not be significant either. Therefore, the disclosed method may improve the performance of the formed semiconductor structure.

Further, the present disclosure also provides a semiconductor structure corresponding to the fabrication method. FIG. 12 illustrates a schematic cross-section view of an exemplary semiconductor structure consistent with various embodiments of the present disclosure.

Referring to FIG. 12, the semiconductor structure may include a substrate 200. The substrate 200 may further include a first region I, a second region II, and a dielectric layer 210 formed on the substrate 200 in both the first region I and the second region II. The dielectric layer 210 may have a first opening in the first region I and a second opening in the second region II. The semiconductor structure may also include a functional layer 211 covering the bottom and the sidewall surfaces of the first opening and the second opening. The first portion of the functional layer 211 formed on the bottom and the sidewall surfaces of the first opening may contain first work function adjusting ions, and the second portion of the functional layer 211 formed on the bottom and the sidewall surfaces of the second opening may contain second work function adjusting ions. The semiconductor structure may further include a work function layer 230 formed on the functional layer 211 in both the first opening and the second opening, and a gate electrode layer 240 formed on the work function layer 230 in each of the first opening and the second opening.

Moreover, the functional layer may be made of one or more of HfO₂, La₂O₃, HfSiON, HfAlO₂, ZrO₂, Al₂O₃, HfSiO₄, etc. In one embodiment, the first region may be used to form NMOS transistors and the second region may be used to form PMOS transistors. In addition, the first work function adjusting ions may be Ag ions and the second work function adjusting ions may be Al ions.

Further, the first work function adjusting ions and the second work function adjusting ions may be doped into the first portion of the functional layer 211 and the second portion of the functional layer 211, respectively through a fabrication process including the following steps. First, prior to forming the work function layer 230, a first doped layer containing first work function adjusting ions may be formed on the first portion of the functional layer 211 in the first opening. Moreover, a second doped layer containing second work function adjusting ions may be formed on the second portion of the functional layer 211 in the second opening. Further, an annealing process may then be performed to diffuse the first work function adjusting ions in the first doped layer into the first portion of the functional layer 211 formed in the first opening and to diffuse the second work function adjusting ions in the second doped layer into the second portion of the functional layer 211 formed in the second opening. After the annealing process, the first doped layer and the second doped layer may be removed and the work function layer 230 may then be formed on the functional layer 211.

According to the disclosed semiconductor structures, the first doped layer may include first work function adjusting ions and the first work function adjusting ions may be able to adjust the work function of the first portion of the functional layer 211 formed in the first opening, and thus the threshold voltage of the transistor formed in the first region I may be further adjusted. Similarly, the second doped layer may include second work function adjusting ions and the second work function adjusting ions may be able to adjust the work function of the portion of the second functional layer 211 formed in the second opening, and thus the threshold voltage of the transistor formed in the second region II may be further adjusted. Therefore, the threshold voltages of the transistors formed in both the first region I and the second region II may meet different design requirements.

Further, the functional layer 211 in the disclosed semiconductor structure may have a uniform thickness in both the first opening and the second opening. Therefore, along the direction parallel to the surface of the substrate and also along the direction perpendicular to the surface of the substrate, the dimensions of the gate electrode layer formed in the first opening and the dimensions of the gate electrode layer formed in the second opening may be the same. Thus, the disclosed fabrication methods may improve the performance of the formed semiconductor structure.

Compared to existing fabrication methods and semiconductor structures, the disclosed fabrication methods and semiconductor structures may demonstrate several advantages.

According to the disclosed fabrication methods, prior to forming the gate electrode layers, a first doped layer and a second doped layer are formed on the functional layer and an annealing process is performed. During the annealing process, the first work function adjusting ions in the first doped layer can diffuse into the first portion of the functional layer formed on the bottom and the sidewall surfaces of the first opening to adjust the work function of the first portion of the functional layer in the first opening, and thus adjust the threshold voltage of the transistor to be formed in the first region. In the meantime, the second work function adjusting ions in the second doped layer can diffuse into the second portion of the functional layer formed on the bottom and the sidewall surfaces of the second opening to adjust the work function of the second portion of the functional layer in the second opening, and thus adjust the threshold voltage of the transistor to be formed in the second region. Therefore, the threshold voltages of the transistors in the first region and the second region can meet different design requirements.

Moreover, the thickness of the functional layer is uniform in the first opening and the second opening, and prior to forming the gate electrode layers, the first doped layer and the second doped layer are removed. Therefore, along the direction parallel to the surface of the substrate and also along the direction perpendicular to the surface of the substrate, the dimensions of the gate electrode layer in the first opening are the same as the dimensions of the gate electrode layer in the second opening. As such, the properties of the transistors formed in the first region and the second region may be uniform, and the performance of the semiconductor structure may be improved.

Further, the thickness of the functional layer is uniform in the first opening and the second opening, and prior to forming the gate electrode layers, the first doped layer and the second doped layer are removed. Therefore, along the direction parallel to the surface of the substrate and also along the direction perpendicular to the surface of the substrate, the dimensions of the gate electrode layer in the first opening are the same as the dimensions of the gate electrode layer in the second opening. As such, during the etching process performed on the work function layer and the functional layer, along the direction perpendicular to the surface of the substrate, the etching depth in the first opening may be the same as the etching depth in the second opening. Thus, the performance of the transistors formed in both the first region and the second region may be the same. In addition, the etching process may also be easily controlled. Specifically, when the functional layer and the work function layer formed on the sidewalls of the first opening become lower than the top surface of the gate electrode layer in the first opening, damages to the gate electrode layer in the second opening during the etching process may not be significant. In the meantime, when the functional layer and the work function layer formed on the sidewalls of the second opening become lower than the top surface of the gate electrode layer in the second opening, damages to the gate electrode layer in the first opening during the etching process may not be significant either. Therefore, the disclosed method may improve the performance of the formed semiconductor structure.

Moreover, according to the disclosed semiconductor structures, the first doped layer may include first work function adjusting ions and the first work function adjusting ions may be able to adjust the work function of the first portion of the functional layer 211 formed in the first opening, and thus the threshold voltage of the transistor formed in the first region I may be further adjusted. Similarly, the second doped layer may include second work function adjusting ions and the second work function adjusting ions may be able to adjust the work function of the second portion of the functional layer 211 formed in the second opening, and thus the threshold voltage of the transistor formed in the second region II may be further adjusted. Therefore, the threshold voltages of the transistors formed in both the first region I and the second region II may meet different design requirements.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fabricating a semiconductor structure, comprising:
providing a substrate including a first region and a second region;
forming a dielectric layer on the first region and the second region of the substrate, wherein the dielectric layer has a first opening in the first region and a second opening in the second region;
forming a functional layer on bottom and sidewall surfaces of each of the first opening and the second opening;
forming a first doped layer containing first work function adjusting ions on a first portion of the functional layer formed on the bottom and the sidewall surfaces of the first opening;
forming a second doped layer containing second work function adjusting ions on a second portion of the functional layer formed on the bottom and the sidewall surfaces of the second opening;
performing an annealing process to diffuse the first work function adjusting ions into the first portion of the functional layer formed in the first opening and to diffuse the second work function adjusting ions into the second portion of the functional layer formed in the second opening;
removing the first doped layer and the second doped layer;
forming a work function layer on the functional layer in both the first opening and the second opening, after removing the first doped layer and the second doped layer; and
forming a gate electrode layer in each of the first opening and the second opening on the work function layer.

2. The method for fabricating the semiconductor structure according to claim 1, wherein:
the second doped layer is formed after forming the first doped layer.

3. The method for fabricating the semiconductor structure according to claim 2, wherein:
the second doped layer is formed on the first doped layer in the first opening.

4. The method for fabricating the semiconductor structure according to claim 1, wherein:
the first doped layer is formed after forming the second doped layer.

5. The method for fabricating the semiconductor structure according to claim 1, wherein:
the first region is used to form an N-type metal-oxide-semiconductor (NMOS) transistor;
the first work function adjusting ions are Mg ions; and
the first doped layer is made of TiN or TaN.

6. The method for fabricating the semiconductor structure according to claim 5, wherein:
a thickness of the first doped layer is in a range of approximately 8 Å to 10 Å; and
a concentration of the first work function adjusting ions in the first doped layer is in a range of approximately 4E14 atom/cm² to 6E14 atom/cm².

7. The method for fabricating the semiconductor structure according to claim 1, wherein:
the second region is used to form a P-type metal-oxide-semiconductor (PMOS) transistor;
the second work function adjusting ions are Al ions; and
the second doped layer is made of one of AlOₓ, TiN, and TaN.

8. The method for fabricating the semiconductor structure according to claim 7, wherein:
a thickness of the second doped layer is in a range of approximately 8 Å to 10 Å.

9. The method for fabricating the semiconductor structure according to claim 1, wherein:
the functional layer includes a gate dielectric layer formed on the bottom surfaces of the first opening and the second opening.

10. The method for fabricating the semiconductor structure according to claim 9, further including:
a covering layer formed on the gate dielectric layer.

11. The method for fabricating the semiconductor structure according to claim 1, wherein:
the functional layer is made of one or more of HfO₂, La₂O₃, HfSiON, HfAlO₂, ZrO₂, Al₂O₃, and HfSiO₄.

12. The method for fabricating the semiconductor structure according to claim 1, wherein the annealing process include:
an annealing temperature in a range of approximately 750° C. to 900° C.; and
an annealing time in a range of approximately 10 minutes to 30 minutes.

13. The method for fabricating the semiconductor structure according to claim 1, wherein:
the work function layer includes a TiN layer.

14. The method for fabricating the semiconductor structure according to claim 13, wherein:
the work function layer further includes a TaN layer, a Ti—Al layer, or a multilayer structure formed by a TaN layer and a Ti—Al layer.

15. The method for fabricating the semiconductor structure according to claim 13, wherein:
a thickness of the work function layer is in a range of approximately 20 Å to 40 Å.

16. The method for fabricating the semiconductor structure according to claim 1, after forming the gate electrode layer in each of the first opening and the second opening, further including:
etching the functional layer and the work function layer to expose a portion of sidewall surfaces of each gate electrode layer in the first opening and the second opening by the etched functional layer and the etched work function layer.

17. A semiconductor structure, comprising:
a substrate, including a first region and a second region;
a dielectric layer formed on the first region and the second region of the substrate, wherein the dielectric layer has a first opening in the first region and a second opening in the second region;
a functional layer covering bottom and sidewall surfaces of the first opening and the second opening, wherein a first portion of the functional layer formed on the bottom and the sidewall surfaces of the first opening contains first work function adjusting ions, and a second portion of the functional layer formed on the bottom and the sidewall surfaces of the second opening contains second work function adjusting ions;
a work function layer formed on the functional layer in the first opening and the second opening; and
a gate electrode layer formed on the work function layer in each of the first opening and the second opening.

18. The semiconductor structure according to claim 17, wherein:
the functional layer is made of one or more of HfO₂, La₂O₃, HfSiON, HfAlO₂, ZrO₂, Al₂O₃, and HfSiO₄.

19. The semiconductor structure according to claim 17, wherein:
an NMOS transistor is formed on the first region and the first work function adjusting ions include Mg ions; and
a PMOS transistor is formed on the second region and the second work function adjusting ions include Al ions.

20. The semiconductor structure according to claim 17, wherein:
a thickness of the work function layer is in a range of approximately 20 Å to 40 Å.
